(19) United States
(12) Patent Application Publication
(10) Pub. No.: US 2025/0194306 A1
(43) Pub. Date: Jun. 12, 2025

(54) DISPLAY PANEL AND DISPLAY APPARATUS

(71) Applicant: Shanghai Tianma Micro-electronics Co., Ltd., Shanghai (CN)

(72) Inventors: Shouzheng WU, Shanghai (CN); Yuhui LAI, Shanghai (CN); Zhenyu JIA, Shanghai (CN); Yongxin HE, Shanghai (CN); Jujian FU, Shanghai (CN); Yuan DING, Shanghai (CN)

(21) Appl. No.: 18/623,255

(22) Filed: Apr. 1, 2024

(30) Foreign Application Priority Data
Dec. 6, 2023 (CN) 202311668337.5

(51) Int. Cl. H01L 33/48; H01L 25/075; H01L 33/62

(52) U.S. Cl. CPC H10H 20/8506; H01L 25/0753; H01L 25/0756; H10H 20/857

(57) ABSTRACT

A display panel includes a base substate, a defining layer, and a light-emitting device. The defining layer is located over one side of the base substrate and includes a defining part and an opening between defining parts. The opening includes a first opening and a second opening. The defining part has a side surface. The side surface has a first side surface and a second side surface. The side surface also has a first bearing surface between the first side surface and the second side surface. The light-emitting device is located in the opening. The light-emitting device has a first light-emitting device located in the first opening and a second light-emitting device located in the second opening. The first light-emitting device and the second light-emitting device are light-emitting devices of different colors. Moreover, at least a portion of the second light-emitting device is disposed over the first bearing surface.

### CROSS-REFERENCE TO RELATED APPLICATION

This application claims priority to Chinese Patent Application No. 202311668337.5, filed on Dec. 6, 2023, the entire content of which is incorporated herein by reference.

### TECHNICAL FIELD

The present disclosure relates to the field of display technology and, in particular, to a display panel and a display apparatus.

### BACKGROUND

With the development of display technology, performance requirements for a display device are getting increasingly higher. Micro LED display technology has gradually become a mainstream product of next-generation displays due to its low power consumption, long product life, and high brightness. However, Micro LED is restricted by the size, making it particularly difficult to increase the pixel density of a display panel.

### SUMMARY

One aspect of the present disclosure provides a display panel. The display panel includes a base substrate, a defining layer, and a light-emitting device. The defining layer is located over one side of the base substrate. The defining layer has a defining part and an opening between defining parts. The opening includes a first opening and a second opening located over one side of the first opening away from the base substrate. The defining part has a side surface facing the opening. The side surface has a first side surface facing the first opening and a second side surface facing the second opening. The side surface also has a first bearing surface between the first side surface and the second side surface. The light-emitting device is located in the opening. The light-emitting device has a first light-emitting device located in the first opening and a second light-emitting device located in the second opening. The first light-emitting device and the second light-emitting device are light-emitting devices of different colors. Moreover, at least a portion of the second light-emitting device is disposed of over the first bearing surface.

Another aspect of the present disclosure provides a display apparatus. The display apparatus includes a display panel. The display panel includes a base substrate, a defining layer, and a light-emitting device. The defining layer is located over one side of the base substrate. The defining layer has a defining part and an opening between defining parts. The opening includes a first opening and a second opening located over one side of the first opening away from the base substrate. The defining part has a side surface facing the opening. The side surface has a first side surface facing the first opening and a second side surface facing the second opening. The side surface also has a first bearing surface between the first side surface and the second side surface. The light-emitting device is located in the opening. The light-emitting device has a first light-emitting device located in the first opening and a second light-emitting device located in the second opening. The first light-emitting device and the second light-emitting device are light-emitting devices of different colors. Moreover, at least a portion of the second light-emitting device is disposed of over the first bearing surface.

### BRIEF DESCRIPTION OF THE DRAWINGS

The features, advantages, and technical effects of exemplary embodiments of the present disclosure will be described below with reference to the accompanying drawings.

FIG. 1 illustrates a schematic structural diagram of a display panel according to various embodiments of the present disclosure.

FIG. 2 illustrates a schematic cross-sectional structural diagram of A-A in FIG. 1.

FIG. 3 illustrates another schematic cross-sectional structural diagram of A′-A′ in FIG. 1.

FIG. 4 illustrates another schematic cross-sectional structural diagram of A″-A″ in FIG. 1.

FIG. 5 illustrates an enlarged schematic structural diagram of P in FIG. 1.

FIG. 6 illustrates a schematic cross-sectional structural diagram of B-B in FIG. 5.

FIG. 7 illustrates a schematic cross-sectional structural diagram of C-C in FIG. 5.

FIG. 8 illustrates another schematic cross-sectional structural diagram of B′-B′ in FIG. 5.

FIG. 9 illustrates another enlarged schematic structural diagram of P′ in FIG. 1.

FIG. 10 illustrates a schematic cross-sectional structural diagram of E-E in FIG. 9.

FIG. 11 illustrates a schematic cross-sectional structural diagram of D-D in FIG. 5.

FIG. 12 illustrates an enlarged exploded structural diagram of P″ in FIG. 1.

FIG. 13 illustrates an enlarged schematic structural diagram of Q in FIG. 12.

FIG. 14 illustrates another enlarged schematic structural diagram of Q′ in FIG. 12.

FIG. 15 illustrates another schematic structural diagram of a display panel according to various embodiments of the present disclosure.

FIG. 16 illustrates a schematic cross-sectional structural diagram of a display panel according to various embodiments of the present disclosure.

In the drawings, same/similar components have the same/similar reference numerals. The drawings are not drawn to actual scale.

### DETAILED DESCRIPTION OF THE EMBODIMENTS

Features and exemplary embodiments of various aspects of the present disclosure will be described in detail below. In order to better convey the purpose, technical solutions, and advantages, the present disclosure will be described in detail below with reference to accompanying drawings and specific embodiments. It should be understood that the specific embodiments described here are only intended to explain the application, rather than to limit the application. It will be apparent those persons of ordinary skill in the art that the present disclosure can be practiced without some of these specific details. The following description of embodiments is merely intended to provide a better understanding of the present disclosure by illustrating examples thereof.

It should be noted that in the present disclosure, relational terms such as first and second are only used to distinguish one entity or operation from another entity or operation, and do not necessarily imply any actual relationship or order between these entities or operations. Furthermore, terms like “comprise”, “include”, or any variations thereof, are intended to encompass non-exclusive inclusion, such that a process, method, article, or apparatus that comprises a series of elements includes not only those elements explicitly listed but also encompasses other elements not expressly listed, or can also include inherent elements for such processes, methods, articles, or apparatus. In the absence of further limitations, elements limited by statements such as “comprising . . . ” do not exclude additional identical elements in the processes, methods, articles, or apparatus that include the specified elements.

Currently, Micro LEDs are usually used as light-emitting devices in Micro LED display panels. Micro LEDs are restricted by their own size and the required spacing between two adjacent Micro LEDs, which makes it more difficult to increase the pixel density of the display panel.

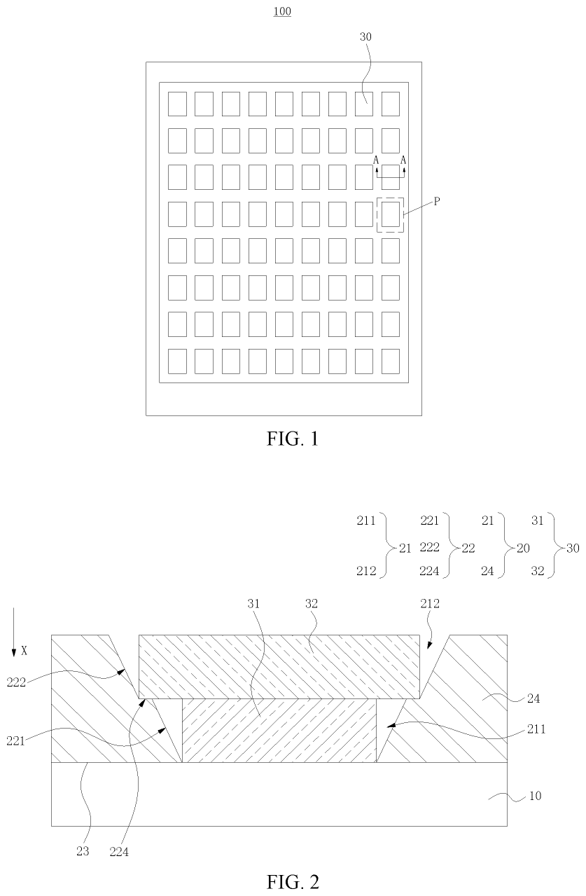

In order to better convey the present disclosure, the display panel and the display apparatus will be described in detail with reference to FIGS. 1 to 16 according to embodiments of the present disclosure.

FIG. 1 is a schematic structural diagram of a display panel according to various embodiments of the present disclosure. FIG. 2 is a schematic cross-sectional structural diagram of A-A in FIG. 1.

As shown in FIG. 1 and FIG. 2, embodiments of the present disclosure provide a display panel 100, which includes a base substrate 10, a defining layer 20, and a light-emitting device 30. The defining layer 20 is located over one side of the substrate 10. The defining layer 20 includes a defining part 24 and an opening 21 that is located between defining parts 24. The opening 21 includes a first opening 211 and a second opening 212 that is located over one side of the first opening 211 away from the base substrate 10. The defining part 24 includes a side surface 22 facing the opening 21. The side surface 22 includes a first side surface 221 facing the first opening 211 and a second side surface 222 facing the second opening 212. The side surface 22 also has a first bearing surface 224 between the first side surface 221 and the second side 222. The light-emitting device 30 is located in the opening 21. The light-emitting device 30 includes a first light-emitting device 31 located in the first opening 211 and a second light-emitting device 32 located in the second opening 212. The first light-emitting device 31 and the second light-emitting device 32 are light-emitting devices 30 with different colors. The second light-emitting device 32 is at least partially disposed on the first bearing surface 224.

The base substrate 10 includes multiple film layer structures. Embodiments of the present disclosure do not limit specific components of a film layer structure of the base substrate 10. As an example, the base substrate 10 can include a substrate and an array layer. The substrate mainly functions a supporting role, and other film layers are stacked on the substrate in sequence. The “stacked on the substrate in sequence” means that the other film layers are arranged in sequence along a direction X perpendicular to the plane of the base. Moreover, a thickness direction of other film layers located over one side of the base substrate 10 is in a same direction as the direction X perpendicular to the plane of the base. Therefore, for the convenience of description, the direction X perpendicular to the plane of the base or the thickness direction of other film layers mentioned later in embodiments of the present disclosure are all illustrated in the same direction.

Optionally, a material of the defining layer 20 includes a black opaque material to reduce the possibility of interference between lights from different openings 21. Alternatively, the definition layer 20 can be provided on the array layer.

The defining layer 20 includes a defining part 24 and an opening 21 located between defining parts 24. The defining part 24 and the opening 21 can be fabricated through a process such as photolithography. During the fabrication process, the first opening 211 and the second opening 212 can be made sequentially. For example, a through hole is made first. A size of the through hole is the same as a size of the first opening 211. Then, the center of the through hole is used as a reference point for etching from one side of the defining layer 20 away from the base substrate 10 to a preset position in the defining layer 20, causing the through hole to form two hole structures with different sizes. One hole structure away from the base substrate 10 is the second opening 212, the other hole structure adjacent to the base substrate 10 is the first opening 211. Of course, the first opening 211 and the second opening 212 can be made together. For example, the defining layer 20 includes a plurality of stacking layers. Each stacking layer is made of different materials, and the first opening 211 and the second opening 212 are formed by controlling the etching rate.

In embodiments of the present disclosure, the defining layer 20 can include a plurality of openings 21, each opening 21 including a first opening 211 and a second opening 212. For example, the plurality of openings 21 are arranged in an array in the display panel 100.

The side surface 22 includes a first side surface 221, a second side surface 222, and a first bearing surface 224. The first side 221 is arranged towards the first opening 211, the second side 222 is arranged towards the second opening 212, and the first bearing surface 224 is arranged between the first side surface 221 and the second side surface 222. That is, the first bearing surface 224 is provided at the junction of the first opening 211 and the second opening 212.

In some embodiments, the first side surface 221 can be an inclined surface. For example, in a direction from the base substrate 10 to the defining layer 20, the first side surface 221 is disposed gradually away from a central axis of the first opening 211. That is, a radius of the first opening 211 gradually increases along the direction from the base substrate 10 to the defining layer 20. In other examples, the first side surface 221 can be a surface perpendicular to a plane of the base substrate 10. Optionally, an arrangement of the second side surface 222 can be the same as an arrangement of the first side surface 221. In some embodiments, the arrangement of the second side surface 222 can also be different than the arrangement of the first side surface 221.

In some embodiments, the first bearing surface 224 can be a surface parallel to the plane of the base substrate 10. For example, a side of the first bearing surface 224 adjacent to the central axis of the first opening 211 is connected to the first side surface 221. A side of the first bearing surface 224 away from the central axis of the first opening 211 is connected to the second side surface 222. In some embodiments, the first bearing surface 224 can be an inclined surface. Taking the first side surface 221 and the second side surface 222 both being inclined surfaces as an example, an inclination angle of the first bearing surface 224 can be different than the inclination angle of the first side surface 221. The inclination angle of the first bearing surface 224 can also be different from the inclination angle of the second side surface 222. In some embodiments, the first side surface 221, the second side surface 222, and the first bearing surface 224 form a continuous surface. The continuous surface is an inclined surface. In a direction from the base substrate 10 to the defining layer 20, the continuous surface is arranged gradually away from the central axis of the opening 211.

In embodiments of the present disclosure, the display panel 100 can be an organic light emitting diode (OLED) display panel, a quantum dot light emitting diode (QLED) display panel, or a micro light emitting diode (Micro LED) display panel, which is not limited here. The following discussion merely takes the display panel 100 is a Micro LED display panel as an example.

In embodiments of the present disclosure, the light-emitting device 30 can be an organic light-emitting film layer in the OLED display panel, a quantum dot layer in the QLED display panel, or an LED in a Micro LED display panel. The following discussion merely takes the light-emitting device 30 being an LED light-emitting device as an example.

The light-emitting device 30 includes a first light-emitting device 31 and a second light-emitting device 32. The first light-emitting device 31 and the second light-emitting device 32 have different colors. For example, the first light-emitting device 31 is a red light-emitting device, and the second light-emitting device 32 is a blue light-emitting device. The first light-emitting device 31 is located in the first opening 211. Optionally, the number of the first light-emitting device 31 in the first opening 211 can be one or more than one. The second light-emitting device 32 is located in the second opening 212. Optionally, the number of the second light-emitting device 32 in the second opening 212 can be one or more than one.

In some embodiments, the opening 21 also includes a third opening 213, a fourth opening 214, a fifth opening 215, and an N-th opening 21N. Correspondingly, the light-emitting device 30 also includes a third light-emitting device 33, a fourth light-emitting device, a fifth light-emitting device, and an N-th light-emitting device. Optionally, taking the third light-emitting device 33 as an example, the third light-emitting device 33 can be disposed in the third opening 213, or the third light-emitting device 33 can also be disposed of in the first opening 211, the second opening 212, or the N-th opening 21N.

The second light-emitting device 32 is at least disposed on the first bearing surface 224. An orthographic projection of the first light-emitting device 31 in the first opening 211 onto the base substrate 10 is not covered by an orthographic projection of the first bearing surface 224 nor covered by an orthographic projection of the second side surface 222 onto the base substrate 10. An orthographic projection of the second opening 212 on the base substrate 10 is greater than an orthographic projection of the first opening 211 on the base substrate 10. Therefore, at least a portion of the surface of the second light-emitting device 32 can be arranged on the first bearing surface 224. Accordingly, taking an example of a quantity of the first light-emitting device 31 and a quantity of the second light-emitting device 32 both being one, an area of an orthographic projection of the first light-emitting device 31 on the base substrate 10 is smaller than an area of an orthographic projection of the second light-emitting device 32 on the base substrate 10.

In the display panel 100 provided in the present disclosure, the first light-emitting device 31 and the second light-emitting device 32 are stacked to reduce the size of a pixel group, increasing the pixel density of the display panel 100. At least a portion of the second light-emitting device 32 is disposed of on the first bearing surface 224. During the transfer process of the first light-emitting device 31 and the second light-emitting device 32, the first light-emitting device 31 and the second light-emitting device 32 can be configured according to their own sizes as well as the first opening 211 and the second opening 212. This is helpful to reduce the possibility of disposing of the light-emitting device 30 in a non-corresponding opening 21, which can improve transferring accuracy and simplify transferring the light-emitting device 30.

As shown in FIG. 2, in some embodiments, the first bearing surface 224 is arranged parallel to the plane of the base substrate 10, which is beneficial to improving the stability of placing the light-emitting device 30 on the first bearing surface 224. Therefore, the first light-emitting device 31 and the second light-emitting device 32 can be transferred using the same tool, which reduces the process difficulty of transferring the light-emitting device 30 to the first bearing surface 224.

Optionally, the plane of the base substrate 10 can be horizontal. Accordingly, the first bearing surface 224 is also horizontal. Optionally, a side surface of the light-emitting device 30 facing the first bearing surface 224 is flat. Thus, the light-emitting device 30 can be placed on the first bearing surface 224.

Optionally, taking an example of the light-emitting device 30 being rectangle-shaped, a shape of a projection of the first bearing surface 224 along a plane perpendicular to the base substrate 10 includes a rectangular annular shape.

As shown in FIG. 2, in some embodiments, the defining part 24 further includes a bottom surface 23 facing the base substrate 10. The first side surface 221 and/or the second side surface 222 form an angle with the bottom surface 23. The angle ranges from 15°˜90°.

It can be understood that an angle between two surfaces is a minimum angle. For example, an angle between the first side surface 221 and the bottom surface 23 is a minimum angle, ranging from 15° to 90°. For example, the angle between the first side surface 221 and the bottom surface 23 includes 15°, 20°, 30°, 40°, 50°, 60°, 70°, 80°, or 90°. An angle between the second side surface 222 and the bottom surface 23 is a minimum angle, ranging from 15° to 90°. For example, the angle between the second side surface 222 and the bottom surface 23 includes 15°, 20°, 30°, 40°, 50°, 60°, 70°, 80°, or 90°.

Optionally, an inclination angle of the first side surface 221 with respect to the bottom surface 23 is the same as an inclination angle of the second side surface 222 with respect to the bottom surface 23. In some embodiments, the inclination angle of the first side surface 221 with respect to the bottom surface 23 is different than the inclination angle of the second side surface 222 with respect to the bottom surface 23.

In embodiments of the present disclosure, the first side surface 221 is inclined away from the center of the first opening 211, that is, an area of the opening 21 of the first opening 211 adjacent to the base substrate 10 is smaller than an area of the opening 21 of the first opening 211 adjacent to the second opening 212. Similarly, the second side surface 222 is inclined away from the center of the second opening 212, that is, an area of the opening 21 of the second opening 212 adjacent to the base substrate 10 is smaller than an area of the opening 21 of the second opening 212 away from the base substrate 10.

In embodiments of the present disclosure, through the above settings, the first side surface 221 and the second side surface 222 can play a guiding role during a transferring process of the light-emitting device 30, which is beneficial to improving the production yield of the light-emitting device 30 during the transfer process and reducing the production cost.

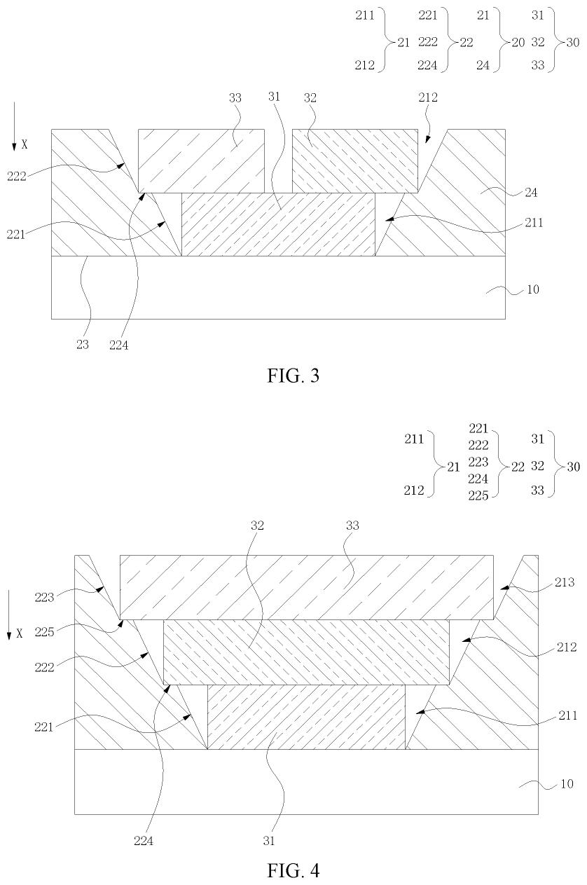

FIG. 3 illustrates another schematic cross-sectional structural diagram of A′-A′ in FIG. 1.

As shown in FIG. 3, in some embodiments, the light-emitting device 30 further includes a third light-emitting device 33. The first light-emitting device 31, the second light-emitting device 32, and the third light-emitting device 33 are light-emitting devices of different colors. The third light-emitting device 33 is arranged in a same layer as one of the first light-emitting device 31 and the second light-emitting device 32.

Optionally, the first light-emitting device 31, the second light-emitting device 32, and the third light-emitting device 33 can be a red light-emitting device, a blue light-emitting device, and green light-emitting device, respectively.

In some embodiments, the first light-emitting device 31 and the third light-emitting device 33 are arranged on a same layer. In some embodiments, the second light-emitting device 32 and the third light-emitting device 33 are arranged on a same layer.

Through the above settings, embodiments of the present application further increase the integration degree of pixels, reduces the plane space occupied by the light-emitting device 30 in the display panel 100, and is conducive to downsizing and miniaturization of the display panel 100.

As shown in FIG. 3, in some embodiments, the third light-emitting device 33 and the second light-emitting device 32 are arranged in the same layer. The third light-emitting device 33 is at least partially arranged on the first bearing surface 224. Among them, the first light-emitting device 31 is a red light-emitting device.

In embodiments of the present disclosure, the first bearing surface 224 can provide supporting force for the second light-emitting device 32 and the third light-emitting device 33 at the same time to ensure that the second light-emitting device 32 and the third light-emitting device 33 are in a same layer. Moreover, the first bearing surface 224 can also improve the parallelism of a light emitted from the second light-emitting device 32 and the third light-emitting device 33.

It is found that a luminous efficiency of the red light-emitting device is lower than that of the blue light-emitting device and that of the green light-emitting device. The embodiments of the present disclosure place the red light-emitting device in a separate layer to improve the light emitting area of the red light-emitting devices. Thus, the uniformity of the luminous efficiency of the first light-emitting device 31, the second light-emitting device 32, and the third light-emitting device 33 are improved, thereby increasing the service life of the light-emitting device 30.

In some embodiments, the third light-emitting device 33 and the first light-emitting device 31 are arranged in a same layer. The second light-emitting device 32 is the red light-emitting device.

As shown in FIG. 3, in some embodiments, an area of the orthographic projection of the first light-emitting device 31 on the base substrate 10 is larger than an area of the orthogonal projection of the second light-emitting device 32 on the base substrate 10 or an area of the orthogonal projection of the third light-emitting device 33 on the base substrate 10.

In some embodiments, the area of the orthographic projection of the first light-emitting device 31 on the base substrate 10 is larger than the area of the orthogonal projection of the second light-emitting device 32 on the base substrate 10. In some embodiments, the area of the orthographic projection of the first light-emitting device 31 on the base substrate 10 is larger than the area of the orthogonal projection of the third light-emitting device 33 on the base substrate 10. In some embodiments, the area of the orthographic projection of the first light-emitting device 31 on the base substrate 10 is greater than the area of the orthogonal projection of the second light-emitting device 32 on the base substrate 10, and the orthographic projection of the first light-emitting device 31 on base substrate 10 is larger than the area of the orthographic projection of the third light-emitting device 33 on the base substrate 10. It can be understood that an area of the first opening 211 for arranging the light-emitting device 30 is smaller than an area of the second opening 212 for arranging the light-emitting device 30. An area of a projection of the first light-emitting device 31 is larger than at least one of an area of a projection of the second light-emitting device 32 and an area of a projection of the third light-emitting device, rather than the area of the projection of the first light-emitting device 31 on the base substrate 10 is greater than the sum of the area of the projection of the second light-emitting device 32 on the base substrate 10 and the projection of the third light-emitting device 33 on the base substrate 10.

Optionally, the first light-emitting device 31 is the red light-emitting device.

Through the above settings, embodiments of the present disclosure further increase the area of light-emitting of the red light-emitting device to balance the luminous efficiencies of the first light-emitting device 31, the second light-emitting device 32, and the third light-emitting device 33, which is beneficial to improving the service life of the light-emitting device 30. FIG. 4 illustrates another schematic cross-sectional structural diagram of A″-A″ in FIG. 1.

As shown in FIG. 4, in some embodiments, the opening 21 also includes a third opening 213 located over a side of the second opening 212 away from the base substrate 10. The side surface 22 further includes a third side surface 223 facing the third opening 213. The side surface 22 further includes a second bearing surface 225 located between the second side surface 222 and the third side surface 223. The light-emitting device 30 further includes a third light-emitting device 33. At least a portion of the third light-emitting device 33 is disposed over the second bearing surface 225. Among them, the third light-emitting device 33 is the red light-emitting device.

The first opening 211 is connected with the second opening 212 and the third opening 213. In a direction from the base substrate 10 to the first opening 211, the first opening 211, the second opening 212, and the third opening 213 are arranged in sequence. Optionally, an angle between the third side surface 223 and the bottom surface 23 ranges from 15° to 90°. Exemplarily, the angle between the third side surface 223 and the bottom surface 23 includes 15°, 20°, 30°, 40°, 50°, 60°, 70°, 80°, or 90°.

Optionally, the second bearing surface 225 may be disposed parallel to the plane of the base substrate 10.

Optionally, an area of the third opening 213 for arranging the light-emitting device 30 can be larger than an area of the first opening 211 for arranging the light-emitting device 30. The area of the third opening 213 for arranging the light-emitting device 30 can be larger than an area of the second opening 212 for arranging the light emitting device 30.

Through the above settings, embodiments of the present disclosure are beneficial to increasing the light-emitting area of the red light-emitting device, and arranging different light-emitting devices 30 in each layer of openings 21. This can reduce the transfer difficulty of the light-emitting devices 30 and improve the production yield.

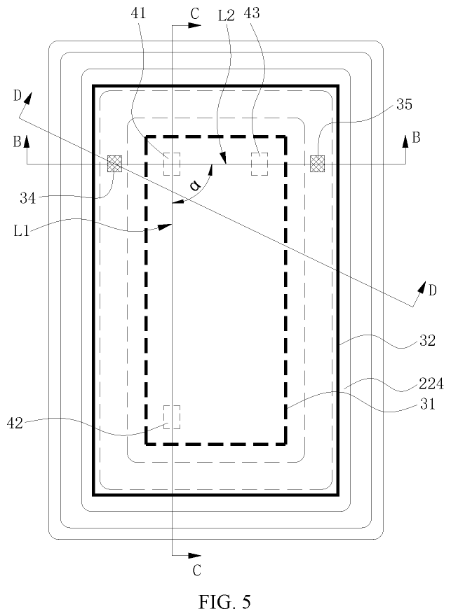

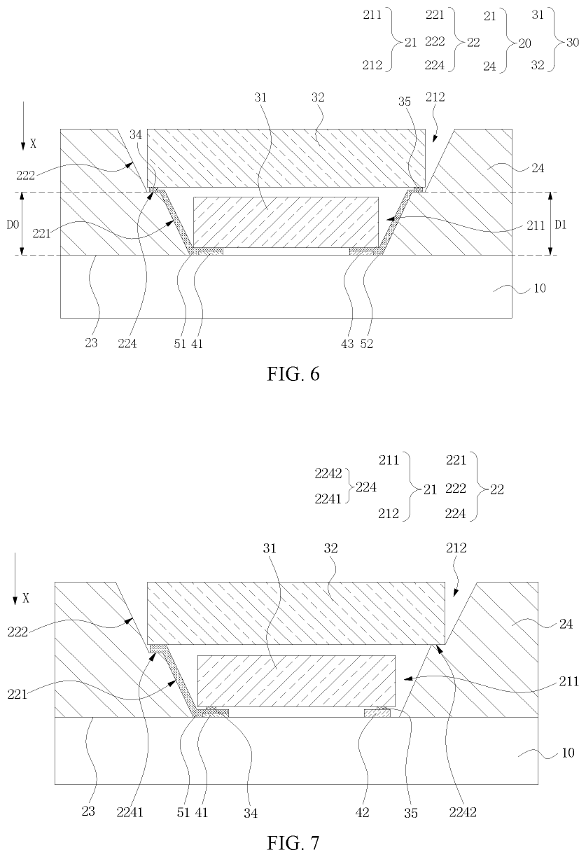

FIG. 5 illustrates an enlarged schematic structural diagram of P in FIG. 1. FIG. 6 illustrates a schematic cross-sectional structural diagram of B-B in FIG. 5. It should be noted that only a first electrode and a second electrode of the second light-emitting device 32 are shown in FIG. 5. A first electrode and a second electrode of the first light-emitting device 31 are not shown.

As shown in FIG. 5 and FIG. 6, in some embodiments, the display panel 100 further includes a common electrode part 41, a first electrode part 42, and a second electrode part 43. The common electrode part 41 connects the first light-emitting device 31 and the second light-emitting device 32. The first electrode part 42 connects the first light-emitting device 31. The second electrode part 43 connects the second light-emitting device 32. An orthographic projection of the first electrode part 42 on the base substrate 10 is a first projection. An orthographic projection of the second electrode part 43 on the base substrate 10 is a second projection. An orthographic projection of the common electrode part 41 on the base substrate 10 is a third projection. A line connecting a center of the first projection and a center of the third projection is a first connection line L1. A line connecting a center of the second projection and the center of the third projection is a second connection line L2. An angle between the first connection line L1 and the second connection line L2 is a, 0°<α≤120°.

In embodiments of the present disclosure, the common electrode part 41, the first electrode part 42, and the second electrode part 43 can serve as a cathode and an anode. For example, the common electrode part 41 is the cathode. The first electrode part 42 and the second electrode part 43 are anodes. Optionally, the common electrode part 41 is the anode. The first electrode part 42 and the second electrode part 43 are cathodes. For better illustrating, embodiments of the present disclosure use the common electrode part 41 as the cathode, while the first electrode part 42 and the second electrode part 43 as the anode.

As an example, the cathode of the first light-emitting device 31 is electrically connected to the common electrode part 41. The anode of the first light-emitting device 31 is electrically connected to the first electrode part 42. The cathode of the second light-emitting device 32 is electrically connected to the common electrode part 41. The anode of the second light-emitting device 32 is electrically connected to the second electrode part 43.

Optionally, each opening 21 exposes a portion of a surface of the base substrate 10. Taking an example of using the portion of the surface of the base substrate 10 of each opening 21 as an installation area, the common electrode part 41, the first electrode part 42, and the second electrode part 43 all can be set in the installation area. Optionally, a plurality of the common electrode parts 41, a plurality of the first electrode parts 42, and a plurality of second electrode parts 43 can be disposed in the display panel 100. Each opening 21 is provided with one common electrode part 41, one first electrode part 42, and one second electrode part 43.

Optionally, a shape of a projection of each installation area on the base substrate 10 can be one of circle, rectangle, or square.

Optionally, a shape of a projection of the common electrode part 41 on the base substrate 10 can be one of circle, rectangle, or square.

Optionally, a shape of a projection of the first electrode part 42 on the base substrate 10 and a shape of a projection of the second electrode part 43 on the base substrate 10 can be the same as the shape of the projection of the common electrode part 41 on the base substrate 10 to facilitate mass production.

As an example, the projection shapes of the common electrode part 41, the first electrode part 42, and the second electrode part 43 on the substrate 10 are all rectangular. That is, the shapes of the first projection, the second projection, and the third projection are all rectangular. For example, the center of the first projection is also the center of the rectangle.

Optionally, a range of an angle a between the first connection line L1 and the second connection line L2 is 0°<α≤120°. Illustratively, a can be 0.1°, 0.5°, 1°, 5°, 10°, 15°, 30°, 60°, 90°, or 120°.

An inclined angle between the first connection line L1 and the second connection line L2 can use the common electrode part 41 as the vertex of the angle. The first electrode part 42 and the second electrode part 43 are electrodes of the same polarity. The first electrode part 42 and the second electrode part 43 are arranged on the side of the included angle, which is beneficial to displacing arrangement positions of an anode of the first light-emitting device 31 and an anode of the second light-emitting device 32. On the one hand, it reduces an alignment accuracy of the first light-emitting device 31 and the second light-emitting device 32 with respect to the opening during the transfer process and reduces the difficulty of transferring. On the other hand, the possibility of interference between anode electrode signals of different light-emitting devices can be reduced, and the risk of mutual influence between anode electrode signals and cathode electrode signals in a same light-emitting device can also be reduced.

As shown in FIG. 5, in some embodiments, α=90°.

When α is 90°, the first connection line L1 and the second connection line L2 are perpendicular. Optionally, the common electrode part 41, the first electrode part 42, and the second electrode part 43 can be disposed at three corners of the installation area. Relative positions of the common electrode part 41, the first electrode part 42, and the second electrode part 43 in the installation area make full use of space of the installation area as much as possible. Moreover, being at a corner can help reduce a distance between the cathode/anode of a light-emitting unit and the common electrode part 41, the first electrode part 42, and the second electrode part 43, along a direction perpendicular to the base substrate 10, improving the reliability of the electrical connection of the light-emitting unit.

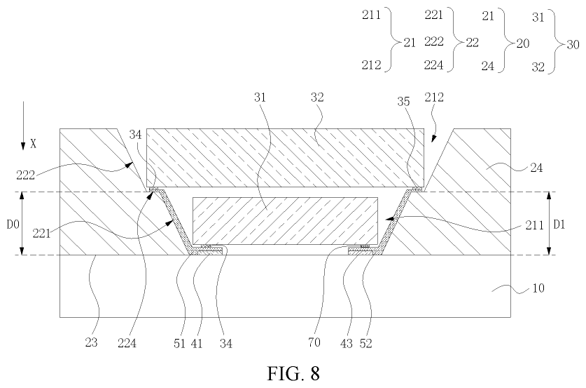

FIG. 7 illustrates a schematic cross-sectional structural diagram of C-C in FIG. 5. FIG. 8 illustrates another schematic cross-sectional structural diagram of B′-B′ in FIG. 5.

As shown in FIG. 5 to FIG. 7, in some embodiments, the common electrode part 41 connects the first light-emitting device 31 and the second light-emitting device 32 through the common conductive part 51. The second electrode part 43 connects the second light-emitting device 32 through the first conductive part 52.

Optionally, the common conductive part 51 can be made of a conductive material. Exemplarily, the common conductive part 51 is made of metal material. For example, the common conductive part 51 is made of aluminum, copper, or silver.

Optionally, the material of the first conductive part 52 can be the same as the material of the common conductive part 51.

Optionally, the common electrode part 41, the first electrode part 42, and the second electrode part 43 can be protruding from the surface of the installation area. That is to say, the common electrode part 41, the first electrode part 42, and the second electrode part 43 all include a side wall and a top wall. The common conductive part 51 can cover the top wall of the common electrode part 41. Or the common conductive part 51 can be provided in contact with the side wall of the common electrode part 4. Similarly, a positional relationship between the second electrode part 43 and the first conductive part 52 can be the same as the positional relationship between the common conductive part 51 and the common electrode part 41, which will not be described again.

As shown in FIG. 5 and FIG. 7, the first light-emitting device 31 can directly cover the installation area. Further, the cathode of the first light-emitting device 31 can directly contact the common electrode portion 41 to achieve electrical connection. The anode of the first light- emitting device 31 can directly contact the first electrode part 42 to achieve electrical connection, thereby simplifying the electrical connection of the first light-emitting device 31.

The common electrode part 41 and the second electrode part 43 need to be electrically connected to the second light-emitting device 32. In order to realize the electrical connection of the second light-emitting device 32, the common conductive part 51 can extend to the first bearing surface 224 from the top wall of the common electrode part 41 through the first side surface 221. Similarly, in order to achieve electrical connection between the second electrode part 43 and the second light-emitting device 32, the first conductive part 52 can extend from the top wall of the second electrode part 43 to the first bearing surface 224 via the first side surface 221.

Through the above settings, embodiments of the present disclosure are beneficial to reducing the difficulty of electrical connection between the light-emitting device 30 and an electrode part, improving the stability of the electrical connection between the light-emitting device 30 and the electrode part, and reducing the possibility of connecting interruption between the light-emitting device 30 and the electrode part.

In some embodiments, as shown in FIG. 8, an insulating pad 70 can be disposed between the first conductive layer and the first light-emitting device 31. Along the direction X perpendicular to the plane of the base, a length of the insulating pad 70 can be same as a length of the first electrode 34. This ensures that when thicknesses of different conductive layers are the same, spacings between the first light-emitting device 31 and each conductive layer are the same to improve the parallelism of the first light-emitting device 31.

As shown in FIG. 6, in some embodiments, along the direction perpendicular to the plane of the base substrate 10, the maximum distance from the first conductive part 52 to the base substrate 10 is D1, and the maximum distance from the common conductive part 51 to the base substrate 10 is D0. Among them, D0>D1.

In some embodiments of the present disclosure, both the first side surface 221 and the second side surface 222 are inclined surfaces. The first conductive part 52 and the common conductive part 51 extend on the first side surface 221 and the second side surface 222. Along a direction perpendicular to the plane of the base substrate 10, the maximum distance from the first conductive part 52 to the base substrate 10 is the distance from an edge of the first conductive part 52 on the side surface 22 of the opening 21 away from the base substrate 10 to the base substrate 10. Along the direction perpendicular to the plane of the base substrate 10, the maximum distance from the common conductive part 51 to the base substrate 10 is the distance from an edge of the common conductive part 51 on the side surface 22 of the opening 21 away from the base substrate 10 to the base substrate 10.

In some embodiments, the opening 21 includes a first opening 211 and a second opening 212. The first light-emitting device 31 is disposed in the first opening 211. The second light-emitting device 32 is disposed in the second opening 212. The common conductive part 51 needs to simultaneously connect the first light-emitting device 31 and the second light-emitting device 32 to the common electrode part 41. That is, the common conductive part 51 needs to extend from the top wall of the common electrode part 41 through the first side surface 221 to the first bearing surface 224. Furthermore, when the opening 21 also includes a third opening 213 and the third light-emitting device 33 is disposed in the third opening 213, the common conductive part 51 also needs to connect the third light-emitting device 33 to the common electrode part 41. that is, the common conductive part 51 needs to extend from the top wall of the common electrode part 41 to the second bearing surface 225 via the first side surface 221, the first bearing surface 224, and the second side surface 222. The first conductive part 52 needs to connect the second electrode part 43 to the second light-emitting device 32. That is, the first conductive part 52 extends from the top wall of the second electrode part 43 through the first side surface 221 to the first bearing surface 224. The first conductive part 52 does not need to be electrically connected to the cathode/anode of the third light-emitting device 33. The first conductive part 52 does not need to extend to the side surface 22 of the third opening 213. That is, the maximum distance between the common conductive part 51 and the base substrate 10 is greater than or equal to the maximum distance from the first conductive part 52 to the base substrate 10.

Embodiments of the present disclosure reduce the redundant arrangement of conductive parts through differentiated settings. This reduces the possibility that the electrical connection between the first conductive part 52 and other light-emitting devices causes other light-emitting devices to accidentally light up.

In some embodiments, in order to reduce the processing difficulty of the conductive part, an extending position of the first conductive part 52 on the side surface 22 of the opening 21 and an extending position of the common conductive part 51 on the side surface 22 of the opening 21 can be disposed in a same position.

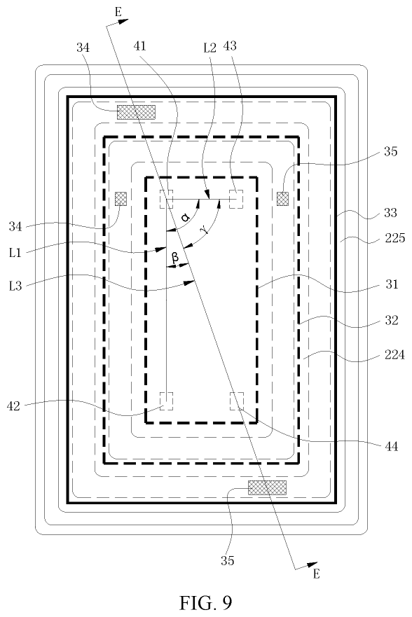

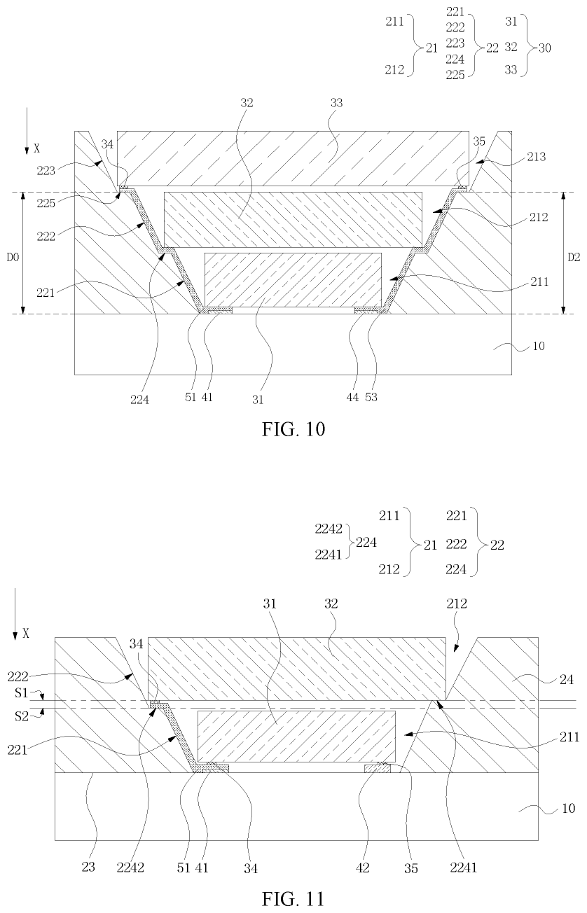

FIG. 9 illustrates another enlarged schematic structural diagram of P′ in FIG. 1. FIG. 10 illustrates a schematic cross-sectional structural diagram of E-E in FIG. 9. It should be noted that only the first electrode and the second electrode of the second light-emitting device 32 are shown in FIG. 9. FIG. 9 further shows the first electrode and the second electrode of the third light-emitting device 33. FIG. 9 does not show the first electrode and the second electrode of the first light-emitting device 31.

As shown in FIG. 9 and FIG. 10, in some embodiments, the light-emitting device 30 further includes a third light-emitting device 33. The third light-emitting device 33 is located over one side of the second light-emitting device 32 away from the base substrate 10. The display panel 100 further includes a third electrode part 44. The third electrode part 44 connects to the third light-emitting device 33 through the second conductive part 53.

Optionally, the third light-emitting device 33 is disposed in the third opening 213. In embodiment of the present disclosure, the similarities between the third light-emitting device 33 and the above-mentioned embodiment will not be described again. The differences will be explained below.

Optionally, the common electrode part 41 is electrically connected to the cathode of the third light-emitting device 33 through the common conductive part 51. The third electrode part 44 is electrically connected to the anode of the third light-emitting device 33 through the second conductive part 53.

Optionally, the second conductive part 53 can cover the top wall of the third electrode part 44, or the second conductive part 53 can be disposed in contact with the side wall of the third electrode part 44. Furthermore, the second conductive portion 53 can extend from the top wall of the third electrode part 44 to the second bearing surface 225 via the first side surface 221, the first bearing surface 224, and the second side surface 222.

Through the above settings, embodiments of the present disclosure are beneficial to reducing the difficulty of electrical connecting the light-emitting device 30 to the electrode part, improving the stability of the electrical connection between the light-emitting device 30 and the electrode part, and reducing the possibilities of interruption between the light-emitting device 30 and the electrode part.

As shown in FIG. 11, some embodiments of the present disclosure include a third conductive part 54. The third conductive part 54 is used for electrical connecting the first electrode part 42 to the second electrode 35 of the first light-emitting device 31. Optionally, along the direction X perpendicular to the plane of the base, the maximum distances between the common conductive part 51, the first conductive part 52, the second conductive part 53, and the third conductive part 54 and the base substrate 10 are all equal.

As shown in FIG. 9, in some embodiments, the orthographic projection of the third electrode part 44 on the base substrate 10 is a fourth projection. A line connecting the center of the fourth projection to the center of the third projection is the third connection line L3. The angle between the first connection line L1 and the third connection line L3 is β. The angle between the second connection line L2 and the third connection line L3 is γ. α, β and γ satisfies relationship: α>β, and α>γ.

Optionally, the third electrode part 44 can be disposed in the installation area. Embodiments of the present disclosure will not describe again about the similarities between the third electrode part 44 and the first electrode part 42 in above embodiments. The differences will be described below. Optionally, α=β+γ.

The angle between the first connection line L1 and the third connection line L3 can take the common electrode part 41 as the vertex of the angle. The angle between the second connection line L2 and the third connection line L3 can take the common electrode part 41 as the vertex of the angle. Then, the third electrode part 44 can be at any positions in the angle between the first connection line L1 and the third connection line L3. Taking the shape of the orthographic projection of the installation area on the base substrate 10 being rectangle as an example, the common electrode part 41, the first electrode part 42, and the second electrode part 43 are at three adjacent corners of the rectangle. The third electrode part 44 is at a corner of the rectangle that are not adjacent to the common electrode part 41. This is beneficial to increase a distance between the third electrode part 44 and the common electrode part 41, increasing the arrangement space for the first conductive part 52 and the second conductive part 53. In some embodiments, β=γ.

Optionally, the third connection line L3 is a line segment located in a line of a bisector line of the angle between the first connection line L1 and the second connection line L2. For example, α is 90°, β is 45°, and γ is 45°.

Embodiments of the present application further increases the spacing between the third electrode part 44 and the common electrode part 41 by setting β=γ. This fully utilizes the space in the installation area and improves the space utilization.

As shown in FIGS. 6 and 10, in some embodiments, along the direction perpendicular to the plane of the base substrate 10, the maximum distance from the second conductive part 53 to the base substrate 10 is D2. Among them, D0≥D2>D1.

In embodiments of the present disclosure, both the first side surface 221 and the second side surface 222 are inclined surfaces. The second conductive part 53 extends on the side surface 22 of the opening 21. Along the direction perpendicular to the plane of the base substrate 10, the maximum distance from the second conductive part 53 to the base substrate 10 is the distance from the edge of the second conductive part 53 on the side surface 22 of the opening 21 away from the base substrate 10 to the base substrate 10.

In embodiments, the common conductive part 51 needs to connect the first light-emitting device 31, the second light-emitting device 32, and the third light-emitting device 33 to the common electrode part 41 at the same time. That is, the common conductive part 51 requires an extension of the top wall of the common electrode part 41 through the first side surface 221, the first bearing surface 224, and the second side surface 222 to the second bearing surface 225. The second conductive part 53 needs connecting the third electrode part 44 to the third light-emitting device 33. That is the second conductive part 53 is formed by extending the top wall of the third electrode part 44 through the first side surface 221, the first bearing surface 224, and the second side surfaces 222 to the second bearing surface 225. That is, the maximum distance between the common conductive part 51 and the base substrate 10 is greater than or equal to the maximum distance between the second conductive part 53 and the base substrate 10.

Embodiments of the present disclosure reduce the redundant arrangement of conductive parts through differentiated settings, and reduce the possibility of accidentally lighting up other light-emitting devices caused by the electrical connection between the second conductive part 53 and other light-emitting devices.

In some embodiments, along the direction perpendicular to the plane of the base substrate 10, the maximum distance from the second conductive part 53 to the base substrate 10 is D2, where, D0=D2=D1.

Through the above arrangement, embodiments of the present application make the extension positions of the common conductive part 51, the first conductive part 52, and the second conductive part 53 on the side surface 22 of the opening 21 are identical. Thus, it eases the manufacturing difficulty of the conductive parts and facilitates mass production of the display panel 100.

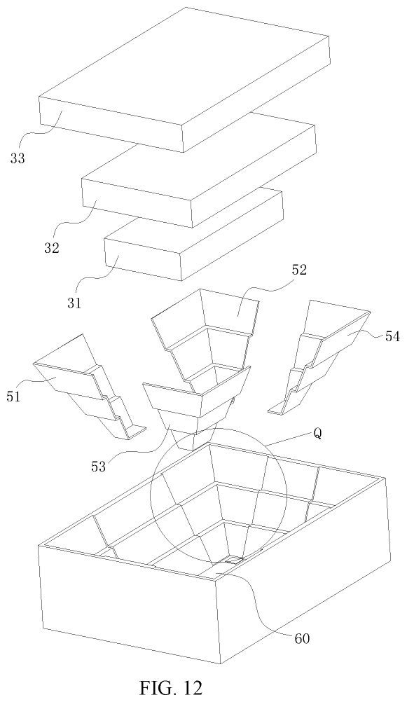

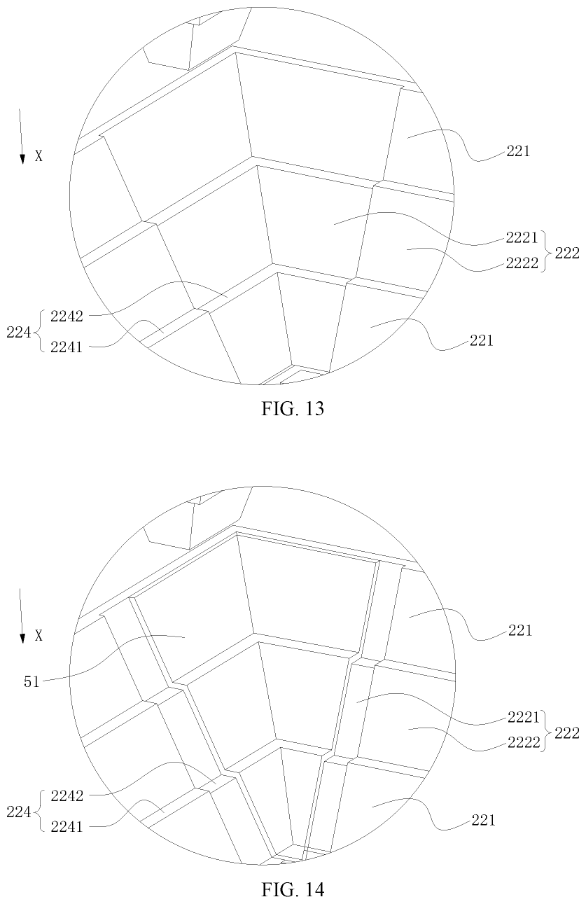

FIG. 11 illustrates a schematic cross-sectional structural diagram of D-D in FIG. 5. FIG. 12 illustrates an enlarged exploded structural diagram of P″ in FIG. 1. FIG. 13 illustrates an enlarged schematic structural diagram of Q in FIG. 12.

As shown in FIGS. 11 to 13, in some embodiments, the first bearing surface 224 includes a first part 2241 and a second part 2242. The first part 2241 is located over a side of the second part 2242 away from the base substrate 10. The light-emitting device 30 includes a first electrode 34 and a second electrode 35. The first electrode 34 and/or the second electrode 35 of the second light-emitting device 32 are disposed in the second part 2242. One surface of the second light-emitting device 32 facing the base substrate 10 at least partially disposed in the first part 2241.

Optionally, along the direction X perpendicular to the plane of the base, a distance between the second part 2242 and the base substrate 10 is smaller than a distance between the first part 2241 and the base substrate 10.

Optionally, the quantity of the first parts 2241 can be one or more. The quantity of the second parts 2242 can be one or more.

As an example, a plurality of first parts 2241 and a plurality of second parts 2242 are alternately arranged. The second part 2242 between two adjacent first parts 2241 and the surface connecting the first part 2241 and the second part 2242 can form a groove. An electrode 34 and a second electrode 35 can be disposed in the groove. A surface of the second light-emitting device 32 facing the base substrate 10 is disposed in the first part 2241. When the second light-emitting device 32 is placed on the bearing surface, the possibility that the plane of the second light-emitting device 32 and the plane of the base substrate 10 intersect is reduced, which is attributed to the electrode are over the surface of the light-emitting device 30 facing the base substrate 10 and the electrode are in contact with the first bearing surface 224. This reduces the possibility of differentiation of light emission directions of the first light-emitting device 31 and the second light-emitting device 32.

Optionally, the distances between the plurality of first parts 2241 along the direction perpendicular to the plane of the base substrate 10 can be the same or different.

As an example, along the direction perpendicular to the plane of the base substrate 10, a distance between a portion of the first part 2241 and the base substrate 10 is greater than a distance between another portion of the first part 2241 and the base substrate 10. Thus, the plane of the second light-emitting device 32 intersects the plane of the base substrate 10. This differentiates light-emitting directions of the second light-emitting device 32 and the first light-emitting device 31. This adjusts the light-emitting directions of the light-emitting devices 30 of different colors, thereby achieving different image effects.

As shown in FIG. 11, in some embodiments, along the direction X perpendicular to the plane of the base, the distance between the first part 2241 and the second part 2242 is greater than or equal to the length of the first electrode 34 and/or the length of second electrode 35.

Along the direction perpendicular to the plane of the base substrate 10, the distance between the first part 2241 and the second part 2242 is also the minimum distance between the plane of the first part 2241 and the plane of the second part 2242. The light-emitting device 30 may include a light-emitting body and a first electrode 34. The first electrode 34 can be formed by protruding from one side surface of the light-emitting body. Here, the “length of the first electrode 34 along the direction perpendicular to the plane of the base substrate 10” refers to is the protruding length of the first electrode 34 from the side surface of the light-emitting body along the direction perpendicular to the plane of the base substrate 10. Through the above arrangement, embodiments of the present disclosure can reduce the influence on the parallelism of the second light-emitting device 32 by the first electrode 34 and the second electrode 35, when the first electrode 34 and the second electrode 35 are disposed on the bearing surface 224.

Optionally, the common conductive part 51 and the first conductive part 52 are also extended to the second part 2242 of the first bearing surface 224.

It should be noted that, to better convey the concept, a first plane S1 and a second plane S2 are added in FIG. 11 to represent a distance between the first part 2241 and the second part 2242. The first plane S1 in FIG. 11 is a plane where the first part 2241 of the first bearing surface 224 is located, and the second plane S2 is a plane where the second part 2242 of the first bearing surface 224 is located.

Illustratively, the common conductive part 51 and the first electrode 34 are located in the same second part 2242, and the common conductive part 51 is located between the first electrode 34 and the second part 2242. Optionally, along the direction X perpendicular to the plane of the base, the sum of the length of the common conductive part 51 and the length of the first electrode 34 is greater than or equal to the spacing between the first part 2241 and the second part 2242.

Optionally, the light-emitting device 30 can further include a third light-emitting device 33 located over a side of the second light-emitting device 32 away from the first light-emitting device 31. The second bearing surface 225 can also include a first part 2241 and a second part 2242. The first electrode 34 and the second electrode 35 of the third light-emitting device 33 and the second bearing surface 225 can be arranged in the same manner as the second light-emitting device 32 and the first bearing surface 224, which will not be described again in embodiments of the present disclosure.

FIG. 14 illustrates an enlarged schematic structural diagram of Q′ in FIG. 12.

As shown in FIGS. 13 and 14, in some embodiments, the second side surface 222 includes a third part 2221 and a fourth part 2222. The third part 2221 is located over a side of the fourth part 2222 away from the second light-emitting device 32. The common conductive part 51 is provided in the third part 2221.

Optionally, the quantity of the third part 2221 includes multiple or one.

Optionally, the quantity of the fourth part 2222 includes multiple or one.

As an example, a plurality of third parts 2221 and a plurality of fourth parts 2222 are alternately arranged. The third part 2221 between two adjacent fourth parts 2222 form a groove with a connecting surface of the third part 2221 and the fourth part 2222. The common conductive part 51 is disposed in the groove to reduce the possibility of the common conductive part 51 contacting the side surface of the light-emitting device 30. Optionally, the surface of the common conductive part 51 of the extended portion of the third part 2221 is flush with the surface of the fourth part 2222.

Optionally, the first side surface 221 further include the third part 2221 and the fourth part 2222. Optionally, the common conductive part 51, the first conductive part 52, and the second conductive part 53 can be extended on the third part 2221 of the first side surface 221.

Optionally, the third side surface 223 further include a third part 2221 and a fourth part 2222. Alternatively, the second conductive part 53 can be disposed in the third part 2221.

Through the above arrangement, embodiments of the present disclosure can reduce the arrangement space of the light-emitting device 30 in the opening 21 occupied by the common conductive part 51, reducing the overall volume of the pixel formed by the light-emitting device 30.

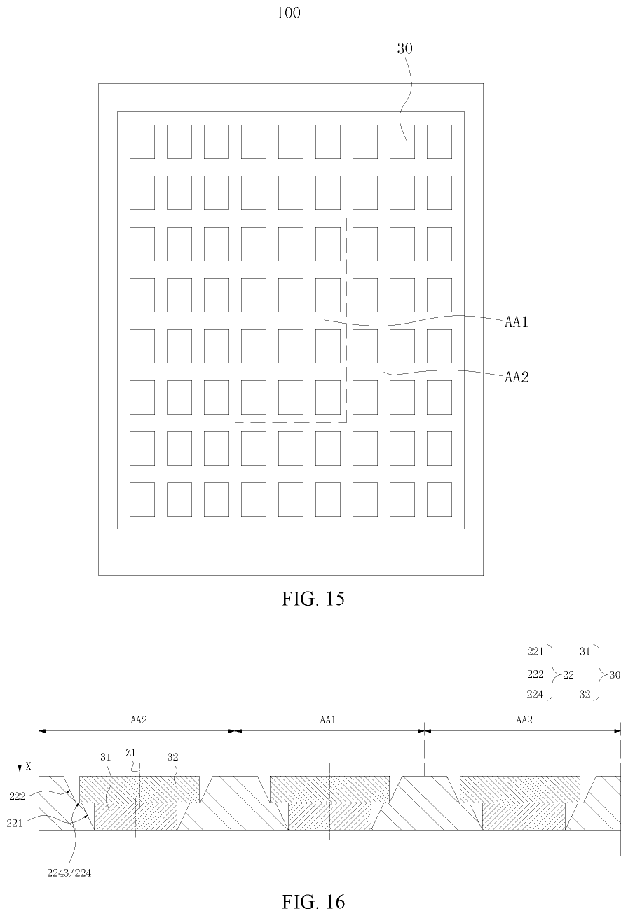

FIG. 15 illustrates a schematic structural diagram of a display panel according to various embodiments of the present disclosure. FIG. 16 illustrates a schematic cross-sectional structural diagram of a display panel according to various embodiments of the present disclosure.

As shown in FIGS. 15 and 16, in some embodiments, the display panel 100 further includes a first area AA1 and a second area AA2 that is at least partially surrounding the first area AA1. In the first area AA1, the symmetry axis Z1 of the light-emitting device 31 is the same as the symmetry axis Z1 of the second light-emitting device 32. In the second area AA2, the symmetry axis Z1 of the first light-emitting device 31 and the symmetry axis Z1 of the second light-emitting device 32 are different.

Optionally, the first area AA1 can be a central area of the display screen. The second area AA2 can be an edge area of the display screen. In some embodiments, the first area AA1 can be a preset area of the display screen. The second area AA2 can be a peripheral area disposed around the preset area.

Taking the stacked first light-emitting device 31 and the second light-emitting device 32 included in the opening 21 as an example, in the second area AA2, the symmetry axis Z1 of the first light-emitting device 31 and the symmetry axis Z1 of the second light-emitting device 32 are different. Thus, a light emitted by the second light-emitting device 32 diffuses more or less to the first area AA1 to adjust the display effect of the first area AA1. Here, “symmetry axes are different” means that the symmetry axis of the first light-emitting device 31 and the second light-emitting device 32 do not coincide with each other. Here, “symmetry axes are same” means that the symmetry axis of the first light-emitting device 31 and the symmetry axis of the second light-emitting device 32 coincide with each other.

Optionally, in the first area AA1, the symmetry axis Z1 of the second light-emitting device 32 is located over one side of the symmetry axis Z1 of the first light-emitting device 31 close to the first area AA1. Thus, the light emitted by the second light-emitting device 32 diffuses more light toward the first area AA1 to increase the brightness of the image in the first area AA1.

Optionally, in the first area AA1, the symmetry axis Z1 of the second light-emitting device 32 is located over one side of the symmetry axis Z1 of the first light-emitting device 31 away from the first area AA1. Thus, the light emitted by the second light-emitting device 32 diffuses less light toward the first area AA1 to reduce the brightness of the image in the first area AA1.

Optionally, the positional relationship between the symmetry axis Z1 of the first light- emitting device 31 and the symmetry axis Z1 of the second light-emitting device 32 can be adjusted by adjusting the position of the second light-emitting device 32 on the first bearing surface 224.

As an example, as shown in FIG. 16, in the second area AA2, the first bearing surface 224 includes a bearing sub-surface 2243. An area of the bearing sub-surface 2243 close to the first area AA1 is larger than that of the bearing sub-surface 2243 away from the first area AA1. This makes the symmetry axis Z1 of the second light-emitting device 32 to be located on the side of the symmetry axis Z1 of the first light-emitting device 31 close to the first area AA1.

Optionally, take the shape of the first area AA1 being rectangle and a long side of the rectangle is parallel to the first direction as an example, the second area AA2 surrounds the first area AA1, and the shape of the second area AA2 is an annular shape. There are second areas AA2 on opposite sides of the first area AA1 along the first direction. The light-emitting devices in the second areas AA2 on opposite sides along the first direction are a first group of light-emitting devices and a second group of light-emitting devices. The distance between the symmetry axis Z1 of the first light-emitting device 31 and the symmetry axis Z1 of the second light-emitting device 32 of each light-emitting device 30 in the first group of light-emitting devices and the distance between the symmetry axis Z1 of the first light-emitting device 31 and the symmetry axis Z1 of the second light-emitting device 32 of each light-emitting device 30 in the second group of light-emitting devices can be same, or of course, different.

Optionally, the symmetry axis Z1 of the second light-emitting device 32 in each light-emitting device 30 in the first group of light-emitting devices can be located on a side of the symmetry axis Z1 of the first light-emitting device 31 close to the first area AA1. The symmetry axis Z1 of the second light emitting device 32 in each light emitting device 30 in the second group of light-emitting devices can be located on a side of the symmetry axis Z1 of the first light emitting device 31 close to the first area AA1. Alternatively, in some embodiments, the symmetry axis Z1 of the second light-emitting device 32 in each light-emitting device 30 in the first group of light-emitting devices can be located on the side of the symmetry axis Z1 of the first light-emitting device 31 close to the first area AA1. The symmetry axis Z1 of the second light-emitting device 32 in each light-emitting device 30 in the second group of light-emitting devices can be located on the side of the symmetry axis Z1 of the first light-emitting device 31 away from the first area AA1.

Optionally, the positional relationship between the symmetry axis Z1 of the third light- emitting device 33 and the symmetry axis Z1 of the first light-emitting device 31 can be same as the positional relationship between the symmetry axis Z1 of the first light-emitting device 31 and the symmetry axis Z1 of the second light-emitting device 32.

As shown in FIG. 12, in some embodiments, the display panel 100 further includes a reflective layer 60. The reflective layer 60 is located on a side of the light-emitting device 30 close to the base substrate 10. The reflective layer 60 is at least partially located in the opening 21.

Optionally, the reflective layer 60 can cover the surface of the base substrate 10.

Optionally, the reflective layer 60 can be an entire layer, or be multiple sub-layers, with each sub-layer located on the exposed surface of each opening 21.

Through the above arrangement, the light scattered by the light-emitting device 30 to the base substrate 10 can be reflected out of the display surface, thereby improving the luminous brightness of the light-emitting device 30.

On the other hand, embodiments of the present disclosure also provide a display device, including any of the above display panels.

Since the display panel provided by embodiments of the present disclosure include the display panel of any of the above embodiments, the beneficial effects of the display panel of any of the above embodiments provided by embodiments of the present disclosure will not be described here again.

While the present disclosure has been described with reference to preferred embodiments, various modifications can be made and equivalents can be substituted for components thereof without departing from the scope of the application. In particular, as long as there is no structural conflict, technical features mentioned in various embodiments can be combined in any way. The present disclosure is not limited to specific embodiments disclosed herein, but includes all technical solutions falling within the scope of the claims.

What is claimed is:

1. A display panel, comprising
a base substrate;
a defining layer located over one side of the base substrate; the defining layer comprises a plurality of defining parts and an opening between defining parts; the opening comprises a first opening and a second opening located over one side of the first opening away from the base substrate; a defining part of the plurality of defining parts comprises a side surface facing the opening; the side surface comprises a first side surface facing the first opening and a second side surface facing the second opening; and the side surface further comprises a first bearing surface between the first side surface and the second side surface; and
a light-emitting device, located in the opening; the light-emitting device comprises a first light-emitting device located in the first opening and a second light-emitting device located in the second opening; and the first light-emitting device and the second light-emitting device are light-emitting devices of different colors, wherein
at least a portion of the second light-emitting device is arranged over the first bearing surface.

2. The display panel according to claim 1, wherein
the first bearing surface is arranged parallel to a plane of the base substrate.

3. The display panel according to claim 1, wherein
the light-emitting device further comprises a third light-emitting device; the first light- emitting device, the second light-emitting device, and the third light-emitting device are light- emitting devices of different colors; and
the third light-emitting device is arranged on a same layer with one of the first light- emitting device and the second light-emitting device.

4. The display panel according to claim 3, wherein
the third light-emitting device is arranged on the same layer with the second light- emitting device, and at least a portion of the third light-emitting device is arranged on the first bearing surface; and the first light-emitting device is a red light-emitting device.

5. The display panel according to claim 4, wherein
an area of an orthographic projection of the first light-emitting device on the base substrate is greater than an area of an orthographic projection of the second light-emitting device or the third light-emitting device on the base substrate.

6. The display panel according to claim 1, wherein
the opening further comprises a third opening located over one side of the second opening away from the base substrate; the side surface further comprises a third side surface facing the third opening and a second bearing surface located between the second side surface and the third side surface;
the light-emitting device further comprises a third light-emitting device, and at least a portion of the third light-emitting device is arranged over the second bearing surface; and
the third light-emitting device is a red light-emitting device.

7. The display panel according to claim 1, further comprising
a common electrode part connecting the first light-emitting device and the second light-emitting device; and
a first electrode part and a second electrode part, wherein the first electrode part connects to the first light-emitting device, and the second electrode part connects to the second light-emitting device, wherein
an orthographic projection of the first electrode part on the base substrate is a first projection, an orthographic projection of the second electrode part on the base substrate is a second projection, and an orthographic projection of the common electrode part on the base substrate is a third projection; a line connecting a center of the first projection to a center of the third projection is a first connection line, and a line connecting a center of the second projection to a center of the third projection is a second connection line; and
an angle between the first connection line and the second connection line is α, 0°<α≥120°.

8. The display panel according to claim 7, wherein α=90°.

9. The display panel according to claim 7, wherein
the common electrode part connects the first light-emitting device and the second light-emitting device through a common conductive part; and
the second electrode part connects to the second light-emitting device through a first conductive part.

10. The display panel according to claim 9, wherein
along a direction perpendicular to a plane of the base substrate, the maximum distance from the first conductive part to the base substrate is D1, and the maximum distance from the common conductive part to the base substrate is D0; and
D0≥D1.

11. The display panel according to claim 10, wherein
the light-emitting device further comprises a third light-emitting device, and the third light-emitting device is located over one side of the second light-emitting device away from the base substrate; and
the display panel further comprises a third electrode part, and the third electrode part connects to the third light-emitting device through a second conductive part.

12. The display panel according to claim 11, wherein
an orthographic projection of the third electrode part on the base substrate is a fourth projection; a line connecting a center of the fourth projection to a center of the third projection is a third connection line; and
an angle between the first connection line and the third connection line is ß, and an angle between the second connection line and the third connection line is γ; α>β, and α>γ.

13. The display panel according to claim 12, wherein β=γ.

14. The display panel according to claim 11, wherein
along the direction perpendicular to the plane of the base substrate, the maximum distance from the second conductive part to the base substrate is D2; and
D0≥D2>D1.

15. The display panel according to claim 11, wherein
along the direction perpendicular to the plane of the base substrate, the maximum distance from the second conductive part to the base substrate is D2; and
D0=D2=D1.

16. The display panel according to claim 1, wherein
the first bearing surface comprises a first part and a second part; the first part is located over one side of the second part away from the base substrate; and
the light-emitting device comprises a first electrode and a second electrode; the first electrode and/or the second electrode of the second light-emitting device are arranged on the second part; and at least a portion of one surface of the second light-emitting device facing the base substrate is arranged on the first part.

17. The display panel according to claim 16, wherein
along a direction perpendicular to a plane of the base substrate, a distance between the first part and the second part is greater than or equal to a length of the first electrode and/or a length of the second electrode.

18. The display panel according to claim 9, wherein
the second side surface comprises a third part and a fourth part, and the third part is located over one side of the fourth part away from the second light-emitting device; and
the common conductive part is arranged in the third part.

19. The display panel according to claim 1, further comprising a first area and a second area, wherein
at least a portion of the second area surrounds the first area;
in the first area, a symmetry axis of the first light-emitting device is same as a symmetry axis of the second light-emitting device; and
in the second area, the symmetry axis of the first light-emitting device is different than the symmetry axis of the second light-emitting device.

20. A display apparatus, comprising:
a display panel, comprising:
a base substrate;
a defining layer located over one side of the base substrate; the defining layer comprises a plurality of defining parts and an opening between defining parts; the opening comprises a first opening and a second opening located over one side of the first opening away from the base substrate; a defining part of the plurality of defining parts comprises a side surface facing the opening; the side surface comprises a first side surface facing the first opening and a second side surface facing the second opening; and
the side surface further comprises a first bearing surface between the first side surface and the second side surface; and
a light-emitting device, located in the opening; the light-emitting device comprises a first light-emitting device located in the first opening and a second light- emitting device located in the second opening; and the first light-emitting device and the second light-emitting device are light-emitting devices of different colors, wherein
at least a portion of the second light-emitting device is arranged over the first bearing surface.
